(19) United States
(12) Patent Application Publication
(10) Pub. No.: US 2005/0051896 A1
(43) Pub. Date: Mar. 10, 2005

(54) Arrangement for improving module reliability

(76) Inventors: Martin Reiss, Ottendorf-Okrilla OT Medingen (DE); Kerstin Nocke, Dresden (DE); Carsten Bender, Dresden (DE)

Correspondence Address: SLATER & MATSIL LLP, 17950 PRESTON ROAD, SUITE 1000, DALLAS, TX, 75252, US

(21) Appl. No.: 10/903,873

(22) Filed: Jul. 30, 2004

(30) Foreign Application Priority Data
Jul. 30, 2003 (DE) 103 35 182.5

(51) Int. Cl. H01L 23/48

(52) U.S. Cl. 257/738; 257/784

(57) ABSTRACT

The invention relates to an arrangement for improving module reliability, in particular the reliability of soldered connections on semiconductor products with BGA or BGA-like components to a substrate on which chips are attached by a die attach material, in particular substrate-based IC packages, solder balls mounted on the side that is opposite from the chip, on contact pads of the substrate on a patterned copper foil, being provided for the electrical connection to printed circuit boards, and the chip and the substrate on the chip side being encapsulated with a mold cap. With the invention, it is intended to provide an arrangement for improving module reliability with which stress acting on the solder balls during alternating thermal loading is reduced. According to the invention, an intermediate layer (3) which consists of a compliant or flexible material is arranged at least between the contact pads (2) and the substrate (1) or the printed circuit board.

This application claims priority to German Patent Application 103 35 182.5, which was filed Jul. 30, 2003 and is incorporated herein by reference.

### TECHNICAL FIELD

The present invention relates generally to electronic component packing and more particularly to an arrangement for improving module reliability.

### BACKGROUND

Substrate-based IC packages of this type are also referred to as BGA packages, BGA standing for Ball Grid Array. U.S. Pat. No. 6,048,755 A discloses a BGA package of this type. It goes without saying that a number of chips or packages may also be arranged on a common substrate strip (matrix strip). The substrate itself comprises a customary PCB (Printed Circuit Board), preferably in the form of a glass-fiber laminate. This glass-fiber laminate is laminated with a copper foil, which has been patterned by means of photolithography or laser patterning or the like, whereby conductor tracks and so-called landing pads for the solder balls have been created.

In the case of substrate-based packages of this type, the mold cap, consisting of a plastics material, serves for protecting the chip and also for protecting the chip edges. The mold cap thereby encloses the backside of the chip and adjacent regions of the substrate, so that adequate protection of the sensitive chip edges is achieved. In the case of these packages, the chip may be fixed on the substrate in various ways. For instance, the chips are usually attached on the substrate by means of a tape or a printed or dispensed adhesive while adequate contact pressure is exerted. It is particularly effective to print the adhesive onto the substrate with a printing stencil interposed and subsequently adhesively bond the chip onto the substrate. This is followed by an electrical connection of the bonding pads of the chips to contact pads on the PCB with the aid of wire bridges, which are drawn through a bonding channel in the PCB. The bonding channel is subsequently sealed with a molding compound to protect the wire bridges.

In the case of these substrate-based packages for integrated circuits, in particular in the case of ball grid arrays with backside protection, difficulties continue to exist with respect to their reliability. This relates in particular to the thermal cycles at module level. The failures caused as a result arise in particular due to detachment of the solder balls during thermal cycles that is during testing of the packages and also during normal use. These detachments are induced by the different coefficients of expansion of the individual materials involved in mounting (chip, substrate, PCB). It has consequently also been found that the adhesion of the copper foil on the substrate is not particularly good, so that thermally induced displacements of the copper foil can lead to detachment of the solder balls.

These detachments of the solder balls then lead to irreparable damage to the package. This problem is particularly marked in the case of very large chips, since here the forces on the solder balls in critical positions are particularly great.

It has been attempted to reduce these problems by making design changes in the bailout of the package (special solder resist masks, or shaping of the solder pads) and alternatively or additionally to use optimized mounting materials. However, it is not possible for time reasons alone to be continually adapting the mounting materials to the chip size, since the adaptation of materials always requires a very large lead-time.

### SUMMARY OF THE INVENTION

In one aspect, the invention relates to an arrangement for improving module reliability, for example the reliability of soldered connections on semiconductor products with BGA or BGA-like components to a substrate on which chips are attached by a die attach material. For example, substrate-based IC packages, solder balls are mounted on the side that is opposite from the chip and on contact pads of the substrate on a patterned copper foil that are provided for the electrical connection to printed circuit boards. The chip and the substrate on the chip side are encapsulated with a mold cap.

The preferred embodiment provides an arrangement for improving module reliability in which the problems demonstrated in the prior art no longer occur. In particular, the stress acting on the solder balls during alternating thermal loading is to be reduced.

In the case of an arrangement for improving module reliability, in particular the reliability of soldered connections on semiconductor products with BGA or BGA-like components to a substrate on which chips are attached by a die attach material, in particular substrate-based IC packages, solder balls mounted on the side that is opposite from the chip, on contact pads of the substrate, being provided for the electrical connection to printed circuit boards, and the chip and the substrate on the chip side being encapsulated with a mold cap, the object on which the invention is based is achieved by an intermediate layer being arranged at least between the contact pads and the substrate or the printed circuit board.

This solution has the effect that stresses occurring are distributed over larger regions and instances of point loading of the individual solder contacts are reduced.

The intermediate layer may advantageously consist of a compliant or flexible material, or may consist of different materials, such as for example of a plastic, or a resist. Other thermally adequately resistant materials that have a certain elasticity are also suitable.

Preferably, the elastic intermediate layer is arranged under the contact pad and adjacent regions of the copper foil. The intermediate layer extends over the entire surface area of the substrate or the printed circuit board, so that the latter can be laminated over its entire surface area, which makes it possible for this to be accomplished at low cost.

In a further development of the invention, the intermediate layer has been applied by means of an adhesion promoter.

Another low-cost possibility is to spray the intermediate layer onto the substrate before the copper foil is applied.

To delimit the intermediate layer in terms of its surface area, a further refinement of the invention provides that the intermediate layer has been patterned together with the copper layer. In principle, there is of course also the possibility of applying the intermediate layer only partially, which however involves increased expenditure.

A further development of the invention provides that the intermediate layer consists of an epoxy resin, which may also be enriched with a filler.

### BRIEF DESCRIPTION OF THE DRAWINGS

The invention is to be explained in more detail below on the basis of an exemplary embodiment. In the associated drawings:

FIG. 1 shows a schematic representation of the arrangement according to the invention of a patterned elastic intermediate layer under a contact pad; and

FIG. 2 shows the arrangement of an elastic intermediate layer on the entire substrate.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In the description of the exemplary embodiment, reference has deliberately not been made to specific modules with BGA or BGA-like components. But the invention is not restricted to any specific module. What is important, however, is that there is a substrate 1 on which conductor tracks 4 and contact pads 2 (electrically connected to the conductor tracks 4) are arranged. The conductor tracks 4 and the contact pads 2 are usually lithographically patterned from a copper foil laminated onto the substrate 1. The contact pads 2 are intended for receiving solder balls (microballs) 5. These solder balls 5 serve for producing an electrical connection between the contact pads 2 and contact areas on printed circuit boards by soldering. Since the printed circuit board likewise comprises conductor tracks 4 from a lithographically patterned copper foil, only the substrate side is described hereafter. It is noted that the circuit board side may be provided with an identical structure according to the invention.

The essence of the invention is an intermediate layer 3 of a compliant or flexible material arranged at least between the contact pads 2 and the substrate 1. A sufficiently elastic plastic, such as for example an epoxy resin or epoxy resin enriched with a filler, has proven to be suitable for this, a resist also being particularly suitable. Because of the higher temperatures occurring during thermal cycles and in the soldering process, the intermediate layer must consist of a thermally resistant material.

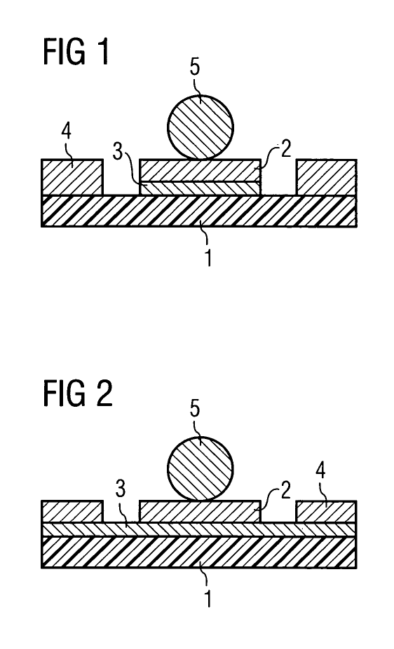

In a way corresponding to FIG. 2, the intermediate layer 3 may extend over the entire surface area of the substrate or of the printed circuit board, which can easily be accomplished by laminating. Subsequently, the copper foil required for the electrical wiring is then laminated onto the intermediate layer 3. The intermediate layer 3 may then be patterned together with the copper layer (FIG. 1), so that the intermediate layer 3 is located only under the conductor tracks 4 and the contact pads 2.

In order to achieve a higher adhesive strength of the intermediate layer 2 on the substrate 1, the intermediate layer 3 may be applied by means of an adhesion promoter.

Another possibility for producing the intermediate layer 3 is to spray it onto the substrate 1.

Although the present invention and its advantages have been described in detail, it should be understood that various changes, substitutions and alterations can be made herein without departing from the spirit and scope of the invention as defined by the appended claims.

1. An electronic component comprising:
a substrate;
a contact pad disposed over the substrate;
a conductor track disposed over the substrate and electrically coupled to the contact pad; and
an intermediate layer disposed between the contact pad and the substrate, the intermediate layer comprising a compliant or flexible material.

2. The electronic component of claim 1 and further comprising a solder ball overlying and electrically coupled to the contact pad.

3. The electronic component of claim 1 and further comprising a chip attached to the substrate on a side opposite of the contact pad.

4. The electronic component of claim 1 wherein the substrate comprises a printed circuit board.

5. The electronic component of claim 1 wherein the intermediate layer comprises a plastic.

6. The electronic component of claim 1 wherein the intermediate layer comprises a resist.

7. The electronic component of claim 1 wherein the intermediate layer comprises a thermally resistant material.

8. The electronic component of claim 1 wherein portions of the intermediate layer are arranged under the conductor track.

9. The electronic component of claim 1 wherein the intermediate layer extends over the entire surface area of the substrate.

10. The electronic component of claim 9 wherein the intermediate layer is laminated over the entire surface area.

11. The electronic component of claim 10 wherein the intermediate layer has been applied by means of an adhesion promoter.

12. The electronic component of claim 1 wherein the intermediate layer has been partially applied.

13. The electronic component of claim 1 wherein the intermediate layer comprises an epoxy resin.

14. The electronic component of claim 13 wherein the epoxy resin is enriched with a filler.

15. An arrangement for improving module reliability, in particular the reliability of soldered connections on semiconductor products with BGA or BGA-like components; the arrangement comprising:
a substrate;
a chip attached to the substrate by a die attach material, the substrate and the chip forming parts of a substrate-based IC package;
solder balls mounted on a side of the substrate that is opposite from a chip, the solder balls mounted on contact pads of the substrate, the contact pads being formed from a patterned copper foil, the patterned copper foil being provided for the electrical connection to printed circuit boards, wherein the chip and the substrate on the chip side are encapsulated with a mold cap; and
an intermediate layer arranged at least between the contact pads and the substrate.

16. A method of forming an electronic component, the method comprising:
providing a substrate;
forming a compliant intermediate layer over the substrate;
forming a conductive layer over the compliant intermediate layer; and
patterning the conductive layer to form a contact pad.

17. The method of claim 16 wherein the intermediate layer has been applied by means of an adhesion promoter.

18. The method of claim 16 wherein forming the compliant intermediate layer comprises spraying on the compliant intermediate layer.

19. The method of claim 16 wherein patterning the conductive layer further comprises patterning the compliant intermediate layer.

20. The method of claim 16 and further comprising mounting a semiconductor chip on a surface of the substrate, the surface being a surface opposite the surface that the compliant intermediate layer is formed on.

21. The method of claim 20 and further comprising mounting a solder ball to the contact pad.

22. The method of claim 16 wherein the conductive layer comprises a copper foil laminated on the intermediate layer.
